(19) United States
(12) Patent Application Publication
(10) Pub. No.: US 2020/0370175 A1
(43) Pub. Date: Nov. 26, 2020

(54) APPARATUS OPERATING METHOD AND SUBSTRATE PROCESSING APPARATUS

(71) Applicant: ASM IP Holding B.V., Almere (NL)

(72) Inventor: Nobuaki TANABE, Kawasaki-shi (JP)

(73) Assignee: ASM IP Holding B.V., Almere (NL)

(21) Appl. No.: 16/859,583

(22) Filed: Apr. 27, 2020

Related U.S. Application Data
(60) Provisional application No. 62/851,347, filed on May 22, 2019.

(51) Int. Cl. C23C 16/44; C23C 16/02

(52) U.S. Cl. CPC C23C 16/4405; C23C 16/4412; C23C 16/0227

(57) ABSTRACT

Examples of an apparatus operating method includes providing gas to an inside of a reactor chamber to perform processing on a substrate in the inside of the reactor chamber, and providing plasma, not via the reactor chamber, to a discharge line communicating with the reactor chamber or a dry pump communicating with the discharge line during loading or unloading of the substrate to/from the reactor chamber to perform cleaning of at least one of the discharge line and the dry pump.

### TECHNICAL FIELD

Examples are described which relate to an apparatus operating method and a substrate processing apparatus.

### BACKGROUND

Gas provided to a reactor chamber is externally discharged via a discharge line by a dry pump. For example, in a process causing many and much by-products, deposits arise in the discharge line or in the dry pump. Such deposits disturb operation of an apparatus or cause locking of the dry pump based on a protecting function of the dry pump. For example, with a roots-type vacuum pump, a lot of deposits cause poor rotation of the impellers.

By providing cleaning gas to the discharge line from a remote plasma unit via the reactor chamber, the discharge line and the dry pump can be suppressed from being occluded. However, since such cleaning interrupts processes in the reactor chamber, this has been a factor of delaying the processes of the apparatus. It can also be said that this causes deterioration of throughput thereof.

### SUMMARY

Some examples described herein may address the above-described problems. Some examples described herein may provide an apparatus operating method and a substrate processing apparatus capable of efficiently cleaning a discharge system.

In some examples, an apparatus operating method includes providing gas to an inside of a reactor chamber to perform processing on a substrate in the inside of the reactor chamber, and providing plasma, not via the reactor chamber, to a discharge line communicating with the reactor chamber or a dry pump communicating with the discharge line during loading or unloading of the substrate to/from the reactor chamber to perform cleaning of at least one of the discharge line and the dry pump.

### BRIEF DESCRIPTION OF THE DRAWINGS

FIG. 1 is a diagram exemplarily illustrating an apparatus operating method;

FIG. 2 is a diagram illustrating an exemplary configuration of a substrate processing apparatus;

FIG. 3 is a diagram illustrating another exemplary configuration of a substrate processing apparatus;

FIG. 4 is a perspective view of a substrate processing apparatus according to an example;

FIG. 5 is a diagram illustrating still another exemplary configuration of a substrate processing apparatus;

FIG. 6 is a perspective view illustrating an exemplary configuration of the dry pump;

FIG. 7 is a cross-sectional view illustrating an exemplary configuration of the dry pump; and

FIG. 8 is a diagram illustrating an apparatus operating method according to a modification.

### DETAILED DESCRIPTION

An apparatus operating method and a substrate processing apparatus are described with reference to the drawings. The same or corresponding components are given the same signs and their duplicate description is occasionally omitted.

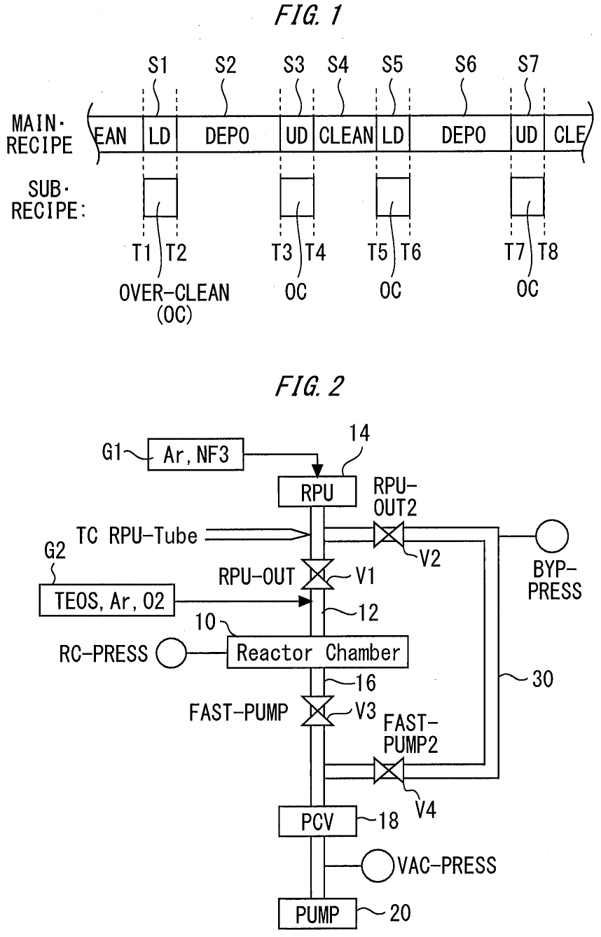

FIG. 1 is a diagram exemplarily illustrating an apparatus operating method. There is explained with this example how an apparatus operates to perform film formation on a substrate in a reactor chamber. The substrate is, for example, a wafer. In the reactor chamber, for example, there may be performed processes of physical vapor deposition, epitaxial deposition, other deposition, diffusion and etching. First, in step S1, a substrate is provided, for example, on a susceptor in the reactor chamber. A time for loading the substrate is, for example, 22 seconds.

Next, in step S2, processing is performed on the substrate. The processing is an exemplarily film formation on the substrate by plasma CVD. The film formation (processing) can be performed by providing gas to the inside of the reactor chamber. Reformation, etching or the like of a film of the substrate may be performed by providing gas to the reactor chamber.

Next, in step S3, the substrate is unloaded. A time for unloading the substrate is, for example, 22 seconds. Next, in step S4, the inside of the reactor chamber is cleaned. According to an example, the reactor chamber is cleaned by providing plasma used for cleaning from a remote plasma unit to the reactor chamber. A time for cleaning the reactor chamber is, for example, 54 seconds.

Next, in step S5, a new substrate is provided to the reactor chamber. In step S6, processing is performed on the substrate. In step S7, the substrate is unloaded.

Such a series of processing in accordance with a main recipe is repeated, and thereby, the processing is sequentially performed on substrates. According to an example, cleaning of the reactor chamber is performed in accordance with the main recipe and cleaning of at least one of a discharge line and a dry pump is performed in accordance with a sub-recipe in parallel to the main recipe. In some examples, the discharge line is a pipe communicating between the reactor chamber and the dry pump. In some examples, the dry pump is a device that removes gas molecules from the reactor chamber. The sub-recipe causes plasma to be provided, not via the reactor chamber, to the discharge line communicating with the reactor chamber or to the dry pump communicating with the discharge line during steps S1 and S5 in which substrates are loaded and steps S3 and S7 in which the substrates are unloaded. In accordance with the sub-recipe, at least one of the discharge line and the dry pump is cleaned in loading and unloading the substrates.

For example, the sum of a time from time T1 to time T2 and a time from time T3 to time T4 can be set to be approximately 65 seconds.

Throughput can be enhanced by simultaneously performing transportation of substrates and cleaning of a discharge system as above.

FIG. 2 is a diagram illustrating an exemplary configuration of a substrate processing apparatus used for the aforementioned apparatus operating method. In a reactor chamber 10, substrates undergo processes such as, for example, film formation, etching and reformation using gas. These processes may include generation of plasma. A remote plasma unit 14 communicates with the reactor chamber 10 via a connection line 12 and can provide plasma to the reactor chamber 10. The remote plasma unit 14 makes gas provided from a gas source G1, such as, for example, Ar or NF₃, into plasma, and provides it as plasma for cleaning to the reactor chamber 10. Meanwhile, in processing of a substrate, gas for film formation is provided to the reactor chamber 10 from a gas source G2 connected to the connection line 12. The gas for film formation can contain TEOS, Ar and O₂, for example.

A discharge line 16 is connected to the reactor chamber 10. Gas in the reactor chamber 10 is discharged via the discharge line 16 by a dry pump 20. The dry pump 20 is, for example, a roots-type dry vacuum pump. Gas used for film formation on a substrate and gas used for cleaning the reactor chamber 10 can be discharged via the discharge line 16 by the dry pump 20.

In this apparatus, a bypass line 30 is provided to connect the connection line 12 and the discharge line 16. The bypass line 30 is a path to enable cleaning gas to be provided, not via the reactor chamber 10, to the discharge line 16 and the dry pump 20 from the remote plasma unit 14.

The substrate processing apparatus as above can realize the apparatus operating method in FIG. 1. In the film formation of step 2, for example, valves V1, V2 and V4 in FIG. 2 are closed and a valve V3 in FIG. 2 is opened, and thereby, a film is formed on a substrate by a method such as plasma CVD or plasma ALD. Of course, supply of process gas is required to form a film. In step 4, the valves V2 and V4 are closed and the valves V1 and V3 are opened, and cleaning gas containing plasma is provided to the reactor chamber 10 from the remote plasma unit 14 via the connection line 12.

When the discharge line 16 and the reactor chamber 10 are cleaned, for example, the valves V1 and V3 are closed and the valves V2 and V4 are opened, and plasma is provided to a large part of the discharge line 16 from the remote plasma unit 14 via the bypass line 30. When a pressure control valve (PCV) 18 suppresses a flow to the reactor chamber 10 via the bypass line 30, the valve V3 may be opened.

In each of the aforementioned steps, the pressure control valve (PCV) 18 can regulate a gas flow rate. The PCV 18 can be used for regulating the amount of plasma provided to the discharge line 16 from the bypass line 30. The PCV is a valve that sets an opening as a percentage so as to attain a pressure designated by a user.

In cleaning the discharge line 16 and the dry pump 20, use of cleaning gas via the bypass line 30, not via the reactor chamber 10, enhances a cleaning rate.

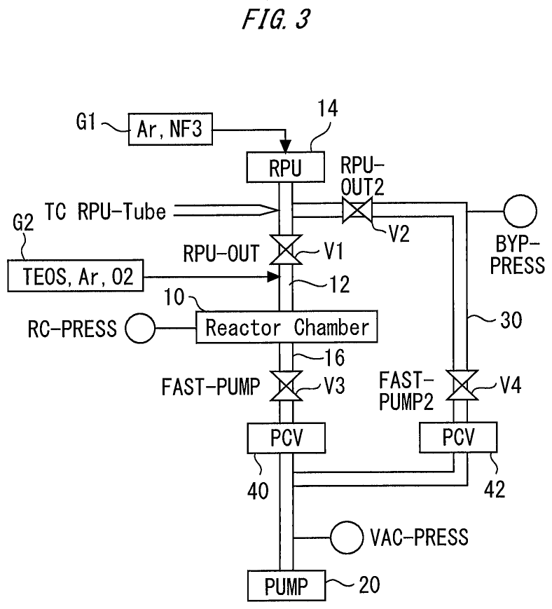

FIG. 3 is a diagram illustrating an exemplary configuration of a substrate processing apparatus according to another example. The apparatus has a PCV 40 on the discharge line 16, and also has a PCV 42 on the bypass line 30. Use of the two PCVs 40 and 42 can enhance flexibility of control. According to other examples, valves and PCVs may be provided at other positions, and some part of the valves and the PCVs in FIGS. 2 and 3 can be omitted.

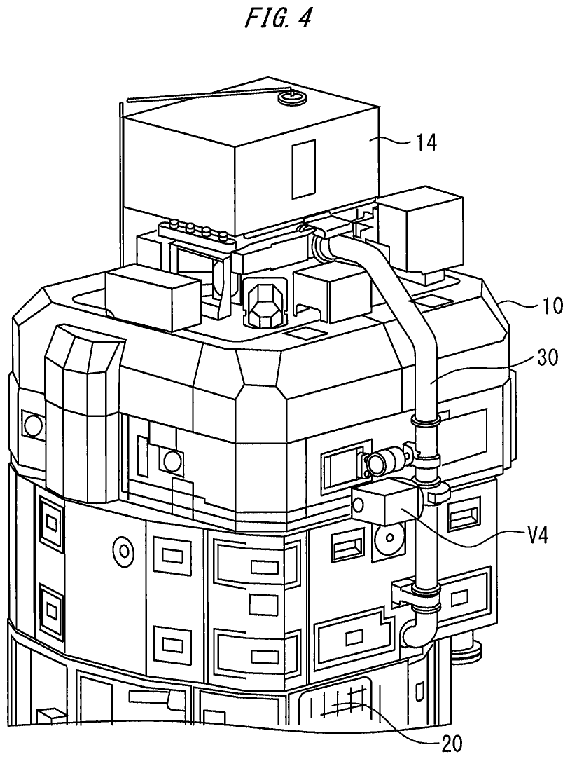

FIG. 4 is a perspective view of a substrate processing apparatus according to an example. According to an example, the remote plasma unit 14 is provided above the reactor chamber 10, and the discharge line is provided below the reactor chamber 10. FIG. 4 illustrates the bypass line 30 being provided along the surface of the reactor chamber 10. The bypass line 30 can be provided along the surface of the reactor chamber 10 in order to attain its minimum path length. Plasma provided from the remote plasma unit 14 can be suppressed from being inactivated by making the bypass line 30 be a curved line or rounding bent parts of the bypass line 30.

FIG. 5 is a diagram illustrating an exemplary configuration of a substrate processing apparatus according to another example. The substrate processing apparatus can be regarded as the dry pump itself having a cleaning function. According to an example, the dry pump 20 communicates with the reactor chamber 10 via the discharge line 16, and is directly connected to an exclusive remote plasma unit 50. The exclusive remote plasma unit 50 and the dry pump 20 communicate with each other via an exclusive line 52. The exclusive remote plasma unit 50 put adjacent to the dry pump 20 can shorten the exclusive line 52. Plasma generated by the exclusive remote plasma unit 50 can coincide with plasma generated by the remote plasma unit 14.

In this example, in accordance with the sub-recipe, plasma is directly provided to the dry pump 20 by the exclusive remote plasma unit 50. Cleaning of the discharge line 16 can be performed with plasma via the reactor chamber 10. Use of the exclusive remote plasma unit 50 can efficiently remove deposits in the dry pump 20.

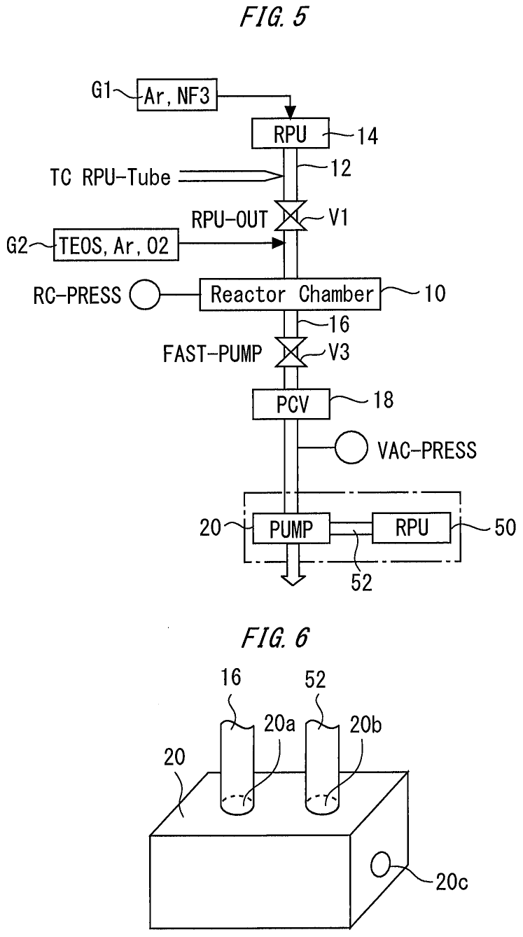

FIG. 6 is a perspective view illustrating an exemplary configuration of the dry pump 20 in FIG. 5. This dry pump 20 includes a first inlet 20a communicating with the discharge line 16, a second inlet 20b communicating with the exclusive remote plasma unit 50, and a discharge port 20c.

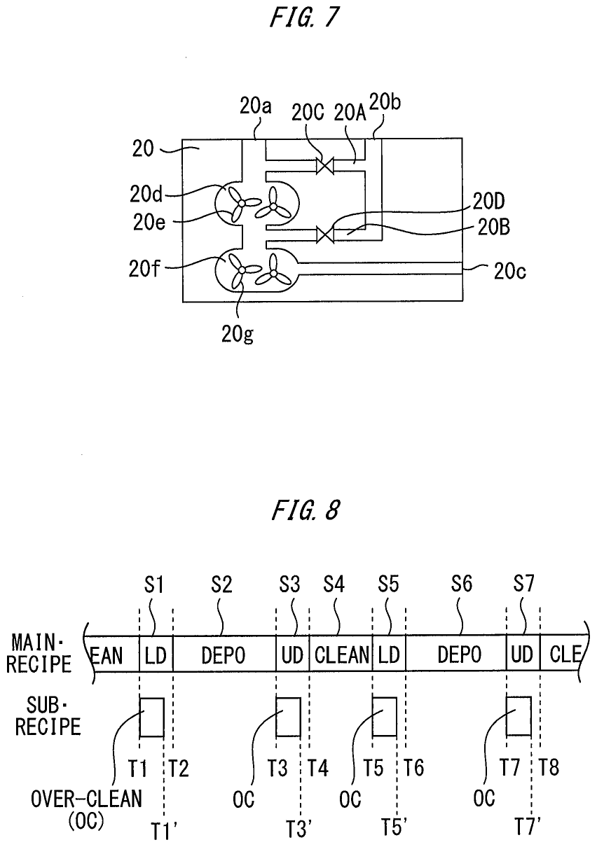

FIG. 7 is a cross-sectional view illustrating an exemplary configuration of the dry pump 20 in FIG. 6. According to an example, there are a plurality of rooms in each of which impellers are provided, inside the dry pump 20. In FIG. 7, there are provided first impellers 20e provided in a first space 20d communicating with the first inlet 20a, and second impellers 20g provided in a second space 20f communicating with the first space 20d. Furthermore, there are provided a first path 20A reaching the first space 20d from the second inlet 20b, and a second path 20B reaching the second space 20f from the second inlet 20b. There can be provided a first valve 20C which opens and closes the first path 20A, a second valve 20D which opens and closes the second path 20B.

The plurality of first impellers 20e and the plurality of second impellers 20g are rotated, and thereby, gas is discharged to the discharge port 20c from the discharge line 16 via the first inlet 20a, the first space 20d and the second space 20f. When deposits arise on the entirety of first impellers 20e and second impellers 20g or on the shaft parts thereof, operation of the dry pump 20 can be disturbed. Such deposits are removed with plasma from the exclusive remote plasma unit 50. For example, the first valve 20C is opened and the second valve 20D is closed, and plasma is provided to the first space 20d from the exclusive remote plasma unit 50 to clean the first space 20d and the first impellers 20e. Furthermore, the first valve 20C is closed and the second valve 20D is opened, and plasma is provided to the second space 20f from the exclusive remote plasma unit 50 to clean the second space 20f and the second impellers 20g. Each impeller can be sufficiently cleaned by providing plasma from the exclusive remote plasma unit 50 individually to the plurality of rooms.

The plasma, described as above, that is generated by the remote plasma unit 14 or the exclusive remote plasma unit 50 and is used for cleaning can be radicals and/or neutral species that is excited in energy. The radicals and/or the neutral species that is excited in energy can be expected to react with gas resulting from the process in the reactor chamber 10, other materials, or deposits into compositions less damaging the apparatus.

FIG. 8 is a diagram illustrating an apparatus operating method according to a modification. In this example, cleaning of at least one of the discharge line and the dry pump is finished before loading or unloading of a substrate is finished. The period from time T1′ when cleaning is finished to time T2 when a film formation process starts allows settings of the opening/closing states of the valves and/or the PCV(s) which settings enable the film formation process to start. Moreover, the period from time T3′ when cleaning is finished to time T4 when cleaning of the reactor chamber starts allows settings of the opening/closing states of the valves and/or the PCV(s) which setting enable the cleaning of the reactor chamber to start. As above, finishing cleaning at least one of the discharge line and the dry pump before loading or unloading of a substrate is finished can contribute further improvement of throughput.

1. An apparatus operating method comprising:
providing gas to an inside of a reactor chamber to perform processing on a substrate in the inside of the reactor chamber; and
providing plasma, not via the reactor chamber, to a discharge line communicating with the reactor chamber or a dry pump communicating with the discharge line during loading or unloading of the substrate to/from the reactor chamber to perform cleaning of at least one of the discharge line and the dry pump.

2. The apparatus operating method according to claim 1, further comprising providing plasma to the reactor chamber from a remote plasma unit that generates plasma used for cleaning via a connection line connecting the remote plasma unit and the reactor chamber to perform cleaning of the reactor chamber.

3. The apparatus operating method according to claim 2, wherein plasma is provided to the discharge line from the remote plasma unit via the bypass line connecting the remote plasma unit and the discharge line when the cleaning of at least one of the discharge line and the dry pump is performed.

4. The apparatus operating method according to claim 3, wherein an amount of plasma provided from the bypass line to the discharge line is regulated by a pressure control valve.

5. The apparatus operating method according to claim 2, wherein plasma is directly provided to the dry pump by an exclusive remote plasma unit separately provided from the remote plasma unit when the cleaning of at least of the discharge line and the dry pump is performed.

6. The apparatus operating method according to claim 5, wherein the dry pump has a plurality of rooms in each of which an impeller that rotates is provided, and plasma of the exclusive remote plasma unit is provided individually to the plurality of the rooms.

7. The apparatus operating method according to claim 1, wherein cleaning of the reactor chamber is performed in accordance with a main recipe, and cleaning of at least one of the discharge line and the dry pump is performed in accordance with a sub-recipe in parallel to the main recipe.

8. The apparatus operating method according to claim 1, wherein cleaning of at least one of the discharge line and the dry pump is finished before loading or unloading of the substrate is finished.

9. A substrate processing apparatus comprising:
a reactor chamber;
a remote plasma unit that communicates with the reactor chamber via a connection line and provides plasma;
a dry pump that communicates with the reactor chamber via a discharge line and discharges gas of the reactor chamber; and
a bypass line connecting the connection line and the discharge line.

10. The substrate processing apparatus according to claim 9, wherein
the remote plasma unit is provided above the reactor chamber, and the discharge line is provided below the reactor chamber, and
the bypass line is provided along a surface of the reactor chamber.

11. The substrate processing apparatus according to claim 10, wherein the bypass line is a curved line.

12. The substrate processing apparatus according to claim 10, wherein a bent part of the bypass line is rounded.

13. A substrate processing apparatus comprising:
a reactor chamber;
a dry pump that communicates with the reactor chamber via a discharge line and discharges gas of the reactor chamber; and
an exclusive remote plasma unit directly connected to the dry pump.

14. The substrate processing apparatus according to claim 13, wherein the dry pump includes a first inlet communicating with the discharge line, a second inlet communicating with the exclusive remote plasma unit, and a discharge port.

15. The substrate processing apparatus according to claim 14, wherein the dry pump has a first impeller provided in a first space communicating with the first inlet and a second impeller provided in a second space communicating with the first space, and a first path reaching the first space from the second inlet and a second path reaching the second space from the second inlet are provided.

16. The substrate processing apparatus according to claim 15, further comprising: a first valve that opens and closes the first path; and a second valve that opens and closes the second path.
